(19) United States
(12) Patent Application Publication
(10) Pub. No.: US 2026/0164720 A1
(43) Pub. Date: Jun. 11, 2026

(54) SEMICONDUCTOR DEVICE

(71) Applicant: Japan Display Inc., Tokyo (JP)

(72) Inventors: Motochika YUKAWA, Tokyo (JP); Akihiro HANADA, Tokyo (JP); Takuo KAITOH, Tokyo (JP); Hajime WATAKABE, Tokyo (JP)

(73) Assignee: Japan Display Inc., Tokyo (JP)

(21) Appl. No.: 19/414,554

(22) Filed: Dec. 10, 2025

(30) Foreign Application Priority Data
Dec. 11, 2024 (JP) 2024-216533
Nov. 7, 2025 (JP) 2025-188266

(51) Int. Cl. H10D 30/67; H10D 30/01

(52) U.S. Cl. CPC H10D 30/6755; H10D 30/031; H10D 30/6736

(57) ABSTRACT

A semiconductor device includes an oxide insulating layer, an oxide semiconductor layer over and in contact with the oxide insulating layer, a gate insulating layer over and in contact with the oxide semiconductor layer, and a gate electrode over the gate insulating layer. A thickness of the gate insulating layer is greater than or equal to 200 nm. The oxide semiconductor layer includes a first region not overlapping the gate electrode in a thickness direction and contains an impurity element. The gate insulating layer includes a second region overlapping the first region in the thickness direction and contains the impurity element. A concentration profile of the impurity element in the thickness direction has a peak in the second region.

### CROSS-REFERENCE TO RELATED APPLICATIONS

This application claims the benefit of priority to Japanese Patent Application Nos. 2024-216533, filed on Dec. 11, 2024 and 2025-188266, filed on Nov. 7, 2025, the entire contents of each are incorporated herein by reference.

### FIELD

An embodiment of the present invention relates to a semiconductor device using an oxide semiconductor.

### BACKGROUND

In recent years, instead of a silicon semiconductor film using amorphous silicon, low-temperature polysilicon, and single crystal silicon, a semiconductor device in which an oxide semiconductor film is used for a channel has been developed (for example, see Japanese laid-open patent publication Nos. 2021-141338, 2014-099601, 2021-153196, 2018-006730, 2016-184771, and 2021-108405). The transistor including an oxide semiconductor layer as a channel has a simple structure and can be manufactured by a low-temperature process, similar to a transistor including an amorphous silicon layer. Further, the transistor including an oxide semiconductor film is known to have a higher field effect mobility than the semiconductor device including an amorphous silicon film.

### SUMMARY

A semiconductor device according to an embodiment of the present invention includes an oxide insulating layer, an oxide semiconductor layer over and in contact with the oxide insulating layer, a gate insulating layer over and in contact with the oxide semiconductor layer, and a gate electrode over the gate insulating layer. A thickness of the gate insulating layer is greater than or equal to 200 nm. The oxide semiconductor layer includes a first region not overlapping the gate electrode in a thickness direction and contains an impurity element. The gate insulating layer includes a second region overlapping the first region in the thickness direction and contains the impurity element. A concentration profile of the impurity element in the thickness direction has a peak in the second region. A concentration of the impurity element in a surface of the first region on the oxide insulating layer side is less than or equal to 5×10¹⁸ cm⁻³. A concentration of the impurity element in a surface of the first region on the gate insulating layer side is greater than or equal to 5×10¹⁹ cm⁻³.

### BRIEF DESCRIPTION OF DRAWINGS

FIG. 1 is a schematic cross-sectional view showing a configuration of a semiconductor device according to an embodiment of the present invention.

FIG. 2 is a schematic plan view showing a configuration of a semiconductor device according to an embodiment of the present invention.

FIG. 3 is a schematic partially enlarged cross-sectional view showing a configuration of a semiconductor device according to an embodiment of the present invention.

FIG. 4 is a graph showing an example of a concentration profile of an impurity element in a semiconductor device according to an embodiment of the present invention.

FIG. 5 is a flowchart illustrating a method for manufacturing a semiconductor device according to an embodiment of the present invention.

FIG. 6 is a schematic cross-sectional view illustrating a method for manufacturing a semiconductor device according to an embodiment of the present invention.

FIG. 7 is a schematic cross-sectional view illustrating a method for manufacturing a semiconductor device according to an embodiment of the present invention.

FIG. 8 is a schematic cross-sectional view illustrating a method for manufacturing a semiconductor device according to an embodiment of the present invention.

FIG. 9 is a schematic cross-sectional view illustrating a method for manufacturing a semiconductor device according to an embodiment of the present invention.

FIG. 10 is a schematic cross-sectional view illustrating a method for manufacturing a semiconductor device according to an embodiment of the present invention.

FIG. 11 is a schematic cross-sectional view illustrating a method for manufacturing a semiconductor device according to an embodiment of the present invention.

FIG. 12 is a schematic cross-sectional view illustrating a method for manufacturing a semiconductor device according to an embodiment of the present invention.

FIG. 13 is a schematic cross-sectional view illustrating a method for manufacturing a semiconductor device according to an embodiment of the present invention.

FIG. 14 is a schematic cross-sectional view illustrating a method for manufacturing a semiconductor device according to an embodiment of the present invention.

FIG. 15 is a schematic cross-sectional view illustrating a method for manufacturing a semiconductor device according to an embodiment of the present invention.

### DESCRIPTION OF EMBODIMENTS

In general, a bottom gate transistor is used in a semiconductor device that requires a high breakdown voltage. However, since parasitic capacitance is generated in the bottom gate transistor, response speed is reduced. On the other hand, when the thickness of the gate insulating film in a top gate transistor in which parasitic capacitance is not generated increases, a breakdown voltage is improved. In this case, however, there is another problem whereby the top gate transistor, the variation of the electrical characteristics is increased.

In view of the above problems, an embodiment of the present invention can provide a semiconductor device having a high breakdown voltage.

Hereinafter, embodiments of the present invention are described with reference to the drawings. The following invention is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the widths, thicknesses, shapes, and the like of components in comparison with the actual embodiments. However, the illustrated shapes are merely examples, and do not limit the interpretation of the present invention. In the present specification and the drawings, the same reference signs are given to components similar to those described previously with respect to the above-described drawings, and detailed description thereof may be omitted as appropriate.

In the specification and the like, a direction from a substrate toward an oxide semiconductor layer is referred to as “on” or “over” in each embodiment of the present invention. Conversely, a direction from the oxide semiconductor layer to the substrate is referred to as “under” or “below.” For convenience of explanation, the phrase “over” or “below” is used for description, but for example, the substrate and the oxide semiconductor layer may be arranged so that the vertical relationship is reversed from that shown in the drawings. Further, the expression “an oxide semiconductor layer on a substrate” merely describes the vertical relationship between the substrate and the oxide semiconductor layer as described above, and another member may be arranged between the substrate and the oxide semiconductor layer. The terms “over” or “below” mean a stacking order in which a plurality of layers is stacked, and may have a positional relationship in which a semiconductor device and a pixel electrode do not overlap in a plan view when expressed as “a pixel electrode over a semiconductor device.” On the other hand, the expression “a pixel electrode vertically over a transistor” means a positional relationship in which the semiconductor device and the pixel electrode overlap in a plan view. In addition, a plan view refers to viewing from a direction perpendicular to a surface of the substrate.

In the specification and the like, the expression “α includes A, B, or C,” “α includes any of A, B, or C,” “α includes one selected from a group consisting of A, B and C,” and the like does not exclude the case where α includes a plurality of combinations of A to C unless otherwise specified. Further, these expressions do not exclude the case where α includes other components.

In the present specification and the like, a “semiconductor device” refers to any device that can function by utilizing semiconductor properties. A transistor and a semiconductor circuit are included in one form of a semiconductor device. For example, the semiconductor device in the following embodiments may be, an integrated circuit (IC) such as a display device or a micro-processing unit (MPU), or a transistor used in a memory circuit.

In the present specification and the like, a “display device” refers to a structure that displays an image using an electro-optic layer. For example, the term “display device” may refer to a display panel that includes the electro-optic layer, or may refer to a structure with other optical members (for example, a polarized member, a backlight, a touch panel, and the like) attached to a display cell. The “electro-optic layer” may include a liquid crystal layer, an electroluminescent (EL) layer, an electrochromic (EC) layer, or an electrophoretic layer, as long as there is no technical contradiction. Therefore, in the embodiments, although a liquid crystal display device including a liquid crystal layer and an organic EL display device including an organic EL layer are described as examples of display devices, structures described in the embodiments can be applied to the other display device including the electro-optical layers described above.

In the specification and the like, the terms “film” and “layer” can be optionally interchanged with one another.

The functions of a source electrode and a drain electrode of a transistor may be interchanged depending on the voltage supplied to each electrode. Therefore, in the present specification and the like, the terms “source electrode” and “drain electrode” may be interchanged in some cases. Similarly, in the specification and the like, the terms “source region” and “drain region” may be interchanged in some cases.

In addition, the following embodiments can be combined with each other as long as there is no technical contradiction.

### 1. Configuration of Semiconductor Device 10

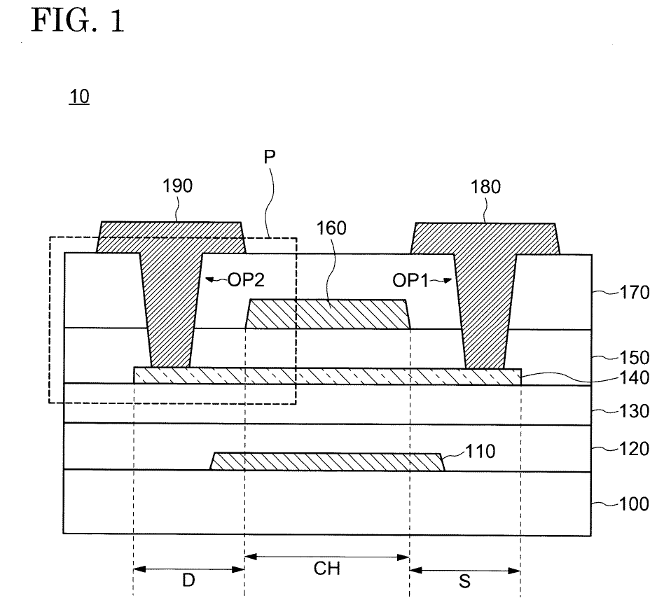

A configuration of a semiconductor device 10 according to an embodiment of the present invention is described with reference to FIGS. 1 to 4.

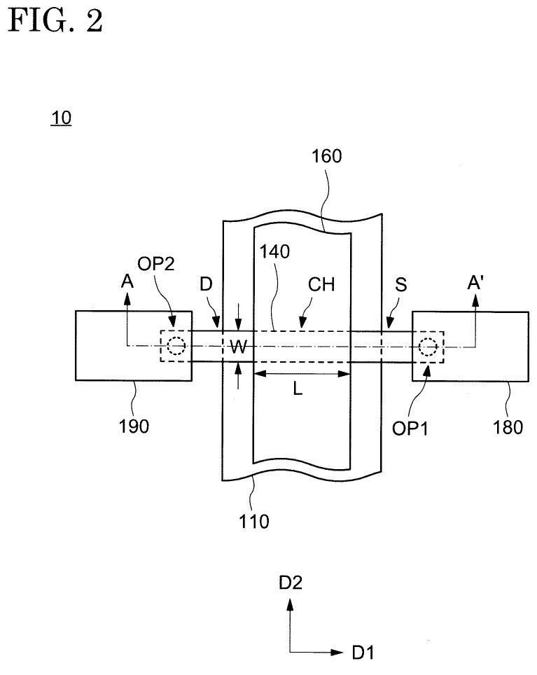

FIG. 1 is a schematic cross-sectional view showing a configuration of the semiconductor device 10 according to an embodiment of the present invention. FIG. 2 is a schematic plan view showing a configuration of the semiconductor device 10 according to an embodiment of the present invention. Specifically, FIG. 1 is a cross-sectional view taken along a line A-A′ in FIG. 2.

As shown in FIG. 1, the semiconductor device 10 includes a substrate 100, a light shielding layer 110, a nitride insulating layer 120, a first oxide insulating layer 130, an oxide semiconductor layer 140, a second oxide insulating layer 150, a gate electrode 160, a third oxide insulating layer 170, a source electrode 180, and a drain electrode 190. The light shielding layer 110 is provided on the substrate 100. The light shielding layer 110 has a predetermined pattern shape. The nitride insulating layer 120 is provided on the substrate 100 so as to cover an upper surface and an end surface of the light shielding layer 110. The first oxide insulating layer 130 is provided on the nitride insulating layer 120. The oxide semiconductor layer 140 is provided on the first oxide insulating layer 130. The oxide semiconductor layer 140 has a predetermined pattern shape and overlaps the light shielding layer 110. The second oxide insulating layer 150 is provided on the first oxide insulating layer 130 so as to cover a top surface and an end surface of the oxide semiconductor layer 140. The gate electrode 160 is provided on the second oxide insulating layer 150. The gate electrode 160 has a predetermined pattern shape and overlaps the light shielding layer 110 and the oxide semiconductor layer 140. The third oxide insulating layer 170 is provided on the second oxide insulating layer 150 so as to cover a top surface and an end surface of the gate electrode 160. The second oxide insulating layer 150 and the third oxide insulating layer 170 have opening portions OP1 and OP2 through which the top surface of the oxide semiconductor layer 140 is exposed. The source electrode 180 is provided on the third oxide insulating layer 170 so as to be in contact with the oxide semiconductor layer 140 through the opening portion OP1. The drain electrode 190 is provided on the third oxide insulating layer 170 so as to be in contact with the oxide semiconductor layer 140 through the opening portion OP2.

The oxide semiconductor layer 140 is divided into a source region S, a drain region D, and a channel region CH based on the gate electrode 160. That is, the oxide semiconductor layer 140 includes the channel region CH which overlaps the gate electrode 160 and the source region S and the drain region D which do not overlap the gate electrode 160. In the thickness direction of the oxide semiconductor layer 140, an edge portion of the channel region CH substantially coincides with an edge portion of the gate electrode 160. The channel region CH is located between the source region S and the drain region D. The channel region CH has semiconductor properties. Each of the source region S and the drain region D contains an impurity element and is conductive. Therefore, the electrical conductivity of the source region S and the drain region D is greater than the electrical conductivity of the channel region CH having semiconductor properties. The source electrode 180 and the drain electrode 190 are in contact with the source region S and the drain region D, respectively, and are electrically connected to the oxide semiconductor layer 140.

As shown in FIG. 2, each of the light shielding layer 110 and the gate electrode 160 has a predetermined width in a first direction D1 and extends in a second direction D2 orthogonal to the first direction D1. A width of the light shielding layer 110 is greater than a width of the gate electrode 160 in the first direction D1. The channel region CH completely overlaps the light shielding layer 110. In the semiconductor device 10, the first direction D1 corresponds to the direction in which current flows from the source electrode 201 to the drain electrode 203 through the oxide semiconductor layer 140. Therefore, a length of the channel region CH in the first direction D1 is a channel length L, and a width of the channel region CH in the second direction D2 is a channel width W.

### 2. Components of Semiconductor Device 10

### [2-1. Substrate 100]

The substrate 100 can support each layer in the semiconductor device 10. For example, a rigid substrate with translucency such as a glass substrate, a quartz substrate, or a sapphire substrate can be used as the substrate 100. Further, a rigid substrate without translucency such as a silicon substrate can be used as the substrate 100. Furthermore, a flexible substrate with translucency such as a polyimide resin substrate, an acrylic resin substrate, a siloxane resin substrate, or a fluorine resin substrate can be used as the substrate 100. In order to improve the heat resistance of the substrate 100, impurities may be introduced into the resin substrate. In addition, a substrate in which a silicon oxide film or a silicon nitride film is formed over the rigid substrate or the flexible substrate described above can be used as the substrate 100.

### [2-2. Light Shielding Layer 110]

The light shielding layer 110 can reflect or absorb external light incident through the substrate 100. Since the light shielding layer 110 is provided to have an area larger than the channel region CH of the oxide semiconductor layer 140, the light shielding layer 110 can block external light entering the channel region CH from the substrate 100 side. For example, aluminum (Al), copper (Cu), titanium (Ti), molybdenum (Mo), tungsten (W), or alloys or compounds thereof can be used for the light shielding layer 105. For example, although the alloy used for the light shielding layer 110 is molybdenum tungsten (MoW), the alloy is not limited thereto. The light shielding layer 110 may have a single layer structure or a laminated structure.

In addition, when a rigid substrate without translucency is used as the substrate 100, the semiconductor device 10 may be configured without the light shielding layer 110.

### [2-3. Nitride Insulating Layer 120]

The nitride insulating layer 120 can prevent impurities contained in the substrate 100 from diffusing into the oxide semiconductor layer 140. That is, the nitride insulating layer 120 can function as a base film. For example, a nitride insulator such as silicon nitride (SiNₓ), silicon nitride oxide (SiNₓO_{y}), aluminum nitride (AlNₓ), or aluminum nitride oxide (AlNₓO_{y}) and the like are used for the nitride insulating layer 120. Here, silicon nitride oxide (SiNₓO_{y}) and aluminum nitride oxide (AlNₓO_{y}) are nitride compounds that contain a smaller proportion (x>y) of oxygen (O) than nitrogen (N). In addition, for convenience of explanation, silicon nitride (SiNₓ) and silicon nitride oxide (SiNₓO_{y}) may be simply referred to as “silicon nitride” in the following description.

### [2-4. First Oxide Insulating Layer 130]

The first oxide insulating layer 130 can also prevent impurities contained in the substrate 100 from diffusing into the oxide semiconductor layer 140. That is, the first oxide insulating layer 130 can function as a base film. Further, the first oxide insulating layer 130 can supply oxygen to the oxide semiconductor layer 140 by a heat treatment. For example, an oxide insulator such as silicon oxide (SiOₓ), silicon oxynitride (SiOₓN_{y}), aluminum oxide (AlOₓ), or aluminum oxynitride (AlOₓN_{y}) can be used for the first oxide insulating layer 130. Here, silicon oxynitride (SiOₓN_{y}) and aluminum oxynitride (AlOₓN_{y}) are oxide compounds that contain a smaller proportion (x>y) of nitrogen (N) than oxygen (O). In addition, for convenience of explanation, silicon oxide (SiOₓ) and silicon oxynitride (SiOₓN_{y}) may be simply referred to as “silicon oxide” in the following description.

### [2-5. Oxide Semiconductor Layer 140]

The oxide semiconductor layer 140 may have an amorphous structure or a polycrystalline structure.

Although a method for forming the oxide semiconductor layer 140 is described later, the oxide semiconductor layer 140 can be formed by sputtering. The composition of the oxide semiconductor layer 140 formed by sputtering depends on the composition of the sputtering target. The composition of the oxide semiconductor layer 140 is substantially identical to the composition of the sputtering target. In this case, the composition of the metal elements in the oxide semiconductor layer 140 can be determined based on the composition of the metal elements in the sputtering target. The composition of the oxide semiconductor layer 140 may also be determined using X-ray diffraction (XRD). Specifically, the composition of the metal elements in the oxide semiconductor layer 140 can be determined based on the crystal structure and lattice constant of the oxide semiconductor layer 140 obtained by XRD. Further, the composition of the metal elements in the oxide semiconductor layer 140 can also be determined using X-ray fluorescence analysis, electron probe microanalyzer (EPMA) analysis, or the like. In addition, the oxygen contained in the oxide semiconductor layer 140 is not limited thereto because oxygen changes depending on the sputtering process conditions and the like.

### [2-6. Second Oxide Insulating Layer 150]

The second oxide insulating layer 150 can function as a gate insulating film. Further, the second oxide insulating layer 150 can also supply oxygen to the oxide semiconductor layer 140 by a heat treatment. An oxide insulator similar to that of the first oxide insulating layer 130 can be used for the second oxide insulating layer 150.

It is preferable that the second oxide insulating layer 150 has a thickness four or more times that of the oxide semiconductor layer 140. In particular, the second oxide insulating layer 150 preferably has a thickness greater than or equal to 200 nm.

### [2-7. Gate Electrode 160]

The same metal material as the light shielding layer 110 can be used for the gate electrode 160. The gate electrode 160 may have a single layer structure or a laminated structure.

### [2-8. Third Oxide Insulating Layer 170]

The third oxide insulating layer 170 can prevent external impurities (for example, water) from diffusing into the oxide semiconductor layer 140. That is, the third oxide insulating layer 170 can function as a protective film. An oxide insulator similar to that of the first oxide insulating layer 130 or the second oxide insulating layer 150 can be used for the third oxide insulating layer 170.

Further, the third oxide insulating layer 170 not only functions as a protective film but also functions as an oxygen supply film that supplies oxygen to the oxide semiconductor layer 140 or an oxygen release suppression film that suppresses the release of oxygen from the oxide semiconductor layer 140. Therefore, when the third oxide insulating layer 170 is provided so as to be in contact with the oxide semiconductor layer 140, generation of oxygen deficiencies in the channel region CH of the oxide semiconductor layer 140 can be suppressed for a long period of time, and the reliability of the semiconductor device 10 can be improved. In addition, although the configuration in which the third oxide insulating layer 170 is provided as a protective film is described, the third oxide insulating layer 170 can also function as an oxygen supply film that supplies oxygen to the oxide semiconductor layer 140.

In addition, when oxygen is supplied sufficiently to the oxide semiconductor layer 140, a single layer structure of a nitride insulator or a laminated structure including an oxide insulator and a nitride insulator can be used for the protective film instead of the third oxide insulating layer 170.

### [2-9. Source Electrode 180 and Drain Electrode 190]

The same metal material as the light shielding layer 110 can be used for each of the source electrode 180 and the drain electrode 190. The source electrode 180 and the drain electrode 190 may each have a single layer structure or a laminated structure.

Not only a metal material but also a transparent conductive oxide such as indium tin oxide (ITO) or indium zinc oxide (IZO) can be used for each of the source electrode 180 and the drain electrode 190. When a transparent conductive oxide is used for each of the source electrode 180 and the drain electrode 190, the source electrode 180 and the drain electrode 190 are transparent, so that the aperture ratio of the pixel can be improved.

The components of the semiconductor device 10 are described above, and the semiconductor device 10 described above is a so-called top-gate transistor. Various modifications can be applied to the semiconductor device 10. For example, when the light shielding layer 110 has conductivity, the semiconductor device 10 may have a configuration in which the light shielding layer 110 functions as a gate electrode, and the nitride insulating layer 120 and the first oxide insulating layer 130 function as gate insulating layers. In this case, although the semiconductor device 10 is a so-called dual-gate transistor, the total film thickness of the nitride insulating layer 120 and the first oxide insulating layer 130 is larger than the thickness of the second oxide insulating layer 150 so that the gate electrode 160 serves as the main gate electrode. Further, when the light shielding layer 110 has conductivity, the light shielding layer 110 may be a floating electrode and may be electrically connected to the source electrode 180.

### 3. Concentration Profile of Impurity Element

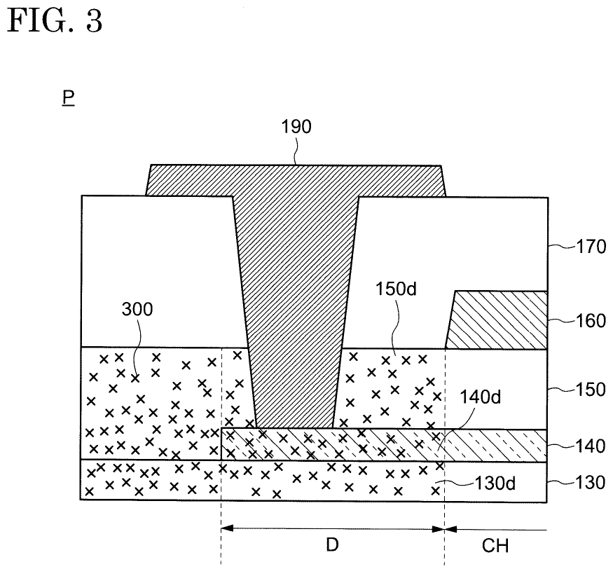

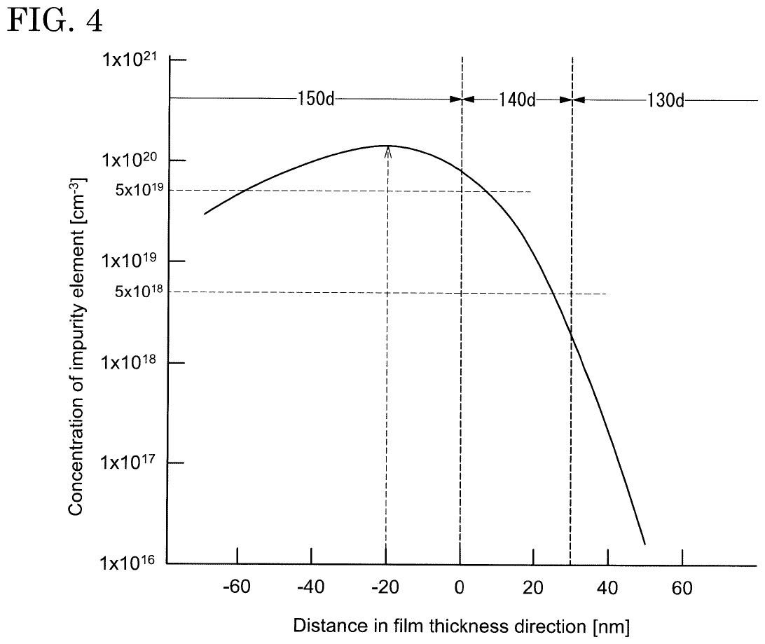

As described above, the source region S and the drain region D of the oxide semiconductor layer 140 contain an impurity element. Although a method for adding the impurity element to the oxide semiconductor layer 140 is described later, the concentration profile of the impurity element is described with reference to FIGS. 3 and 4 in the following description.

FIG. 3 is a schematic partially enlarged cross-sectional view showing a configuration of the semiconductor device 10 according to an embodiment of the present invention. Specifically, FIG. 3 is an enlarged cross-sectional view of a region P in FIG. 1. Although the region P shown in FIG. 3 is a region in the vicinity of the drain region D, the region in the vicinity of the source region S also has a similar configuration to the region P.

As shown in FIG. 3, the impurity element 300 is contained not only in the oxide semiconductor layer 140 but also in the first oxide insulating layer 130 and the second oxide insulating layer 150. In the first oxide insulating layer 130 and the second oxide insulating layer 150, the impurity element 300 is also contained in a region that does not overlap the gate electrode 160. Boron (B), phosphorus (P), argon (Ar), nitrogen (N), or the like can be used as the impurity element.

Here, a region of the oxide semiconductor layer 140 containing the impurity element is referred to as a first region 140d (i.e., corresponding to a source region S or drain region D). Further, a region of the second oxide insulating layer 150 which overlaps the first region 140d in the film thickness direction and contains the impurity element is referred to as a second region 150d. Furthermore, a region of the first oxide insulating layer 130 which overlaps the first region 140d in the film thickness direction and contains the impurity element is referred to as a third region 130d.

FIG. 4 is a graph showing an example of the concentration profile of the impurity element in the semiconductor device 10 according to an embodiment of the present invention. Specifically, FIG. 4 shows the concentration profile of the impurity element in the second region 150d, the first region 140d, and the third region 130d in the film thickness direction.

The horizontal axis in FIG. 4 represents the distance in the film thickness direction, with 0 nm at the interface between the first region 140d and the second region 150d (i.e., the interface between the oxide semiconductor layer 140 and the second oxide insulating layer 150). Further, the direction toward the third region 130d is the positive direction, and the direction toward the second region 150d is the negative direction. As shown in FIG. 4, the impurity element has a concentration profile with a peak in the second region 150d. The peak is located within 50 nm from 0 nm in the negative direction. In other words, the peak is located within 50 nm from the interface between the oxide semiconductor layer 140 and the gate insulating layer. The concentration of the impurity element in the surface of the first region 140d on the second region 150d side (i.e., the second oxide insulating layer 150 side) is greater than or equal to 5×10¹⁹ cm⁻³. The impurity concentration in the surface of the first region 140d on the third region 130d side (that is, on the first oxide insulating layer 130 side) is less than or equal to 5×10¹⁸ cm⁻³.

When the impurity element is added to the oxide semiconductor layer 140, oxygen deficiencies are generated in the oxide semiconductor layer 140. Further, when hydrogen is trapped in the generated oxygen deficiencies, the resistance of the source region S and the drain region D is reduced. It is necessary to reduce the resistance of the source region S and the drain region D in order that the source region S and the drain region D have ohmic contact with the source electrode 180 and the drain electrode 190, respectively. For example, when the thickness of the oxide semiconductor layer 140 is greater than or equal to 10 nm and less than or equal to 50 nm, it is preferable that the sheet resistance of the source region S and the drain region D is less than or equal to 1×10⁴ Ω/sq.

The addition of the impurity element generates oxygen deficiencies in the source region S and the drain region D. That is, the first region 140d includes oxygen deficiencies. Further, the addition of an impurity element also generates dangling bond defects in the second region 150d. At this time, since hydrogen bonds included in the second region 150d are also broken, hydrogen is generated along with the dangling bond defects. When the hydrogen generated in the second region 150d diffuses into the first region 140d, the hydrogen is trapped in the oxygen deficiencies in the first region 140d. As a result, the resistance of the first region 140d is reduced. When the impurity element has the above-described concentration profile, oxygen deficiencies in the first region 140d and hydrogen in the second region 150d are efficiently generated, so that a sheet resistance of the first region 140d is less than or equal to 1×10⁴ Ω/sq.

The semiconductor device 10 is a top-gate transistor. However, unlike typical top-gate transistors, the semiconductor device 10 has a large second oxide insulating layer 150 which functions as a gate insulating film. Therefore, the semiconductor device 10 has a high breakdown voltage. However, when the impurity element is added to the second oxide insulating layer 150, which has a thickness four or more times that of the oxide semiconductor layer 140, a large amount of hydrogen is generated and cannot be trapped by the oxygen deficiencies in the oxide semiconductor layer 140. In this case, since hydrogen diffuses to the channel region CH in which oxygen deficiencies are not generated by the addition of the impurity element, the variation in electrical characteristics occurs. Therefore, in the semiconductor device 10, the concentration profile of the impurity element is adjusted to prevent excessive hydrogen from being generated in the second oxide insulating layer 150. Specifically, the impurity element is controlled to have the above-described concentration profile. As a result, the semiconductor device 10 can not only have a high breakdown voltage but also suppress variations in electrical characteristics.

### 4. Manufacturing Method of Semiconductor Device 10

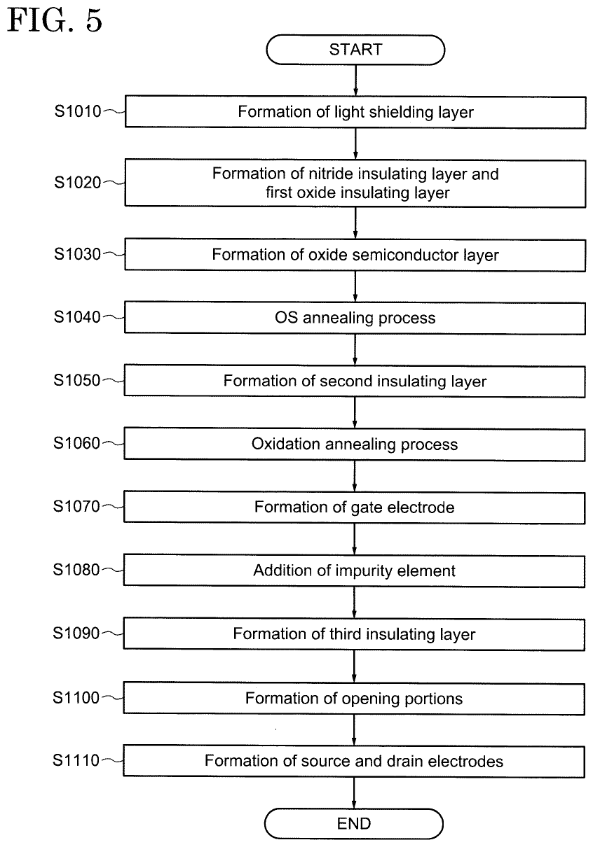

A method for manufacturing the semiconductor device 10 is described with reference to FIGS. 5 to 15.

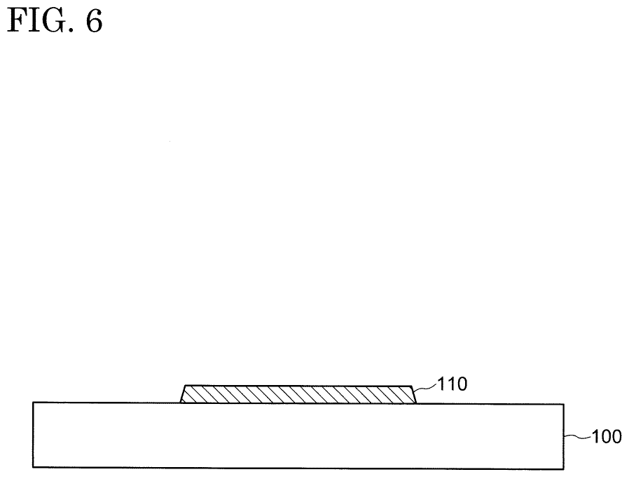

FIG. 5 is a flowchart illustrating a method for manufacturing the semiconductor device 10 according to an embodiment of the present invention. FIGS. 6 to 15 are schematic cross-sectional views illustrating a method for manufacturing the semiconductor device 10 according to an embodiment of the present invention.

As shown in FIG. 5, the method for manufacturing the semiconductor device 10 includes steps S1010 to S1110. Hereinafter, steps S1010 to S1110 are described in this order with reference to FIGS. 6 to 15, as appropriate.

In step S1010, the light shielding layer 110 is deposited on the substrate 100, and then patterned using photolithography. In this way, the light shielding layer 110 having a predetermined pattern shape is formed on the substrate 100 (see FIG. 6). When a metal material is used for the light shielding layer 110, the light shielding layer 110 is deposited by sputtering. Although the thickness of the light shielding layer 110 is not limited to a certain value, the thickness is greater than or equal to 50 nm and less than or equal to 300 nm, for example.

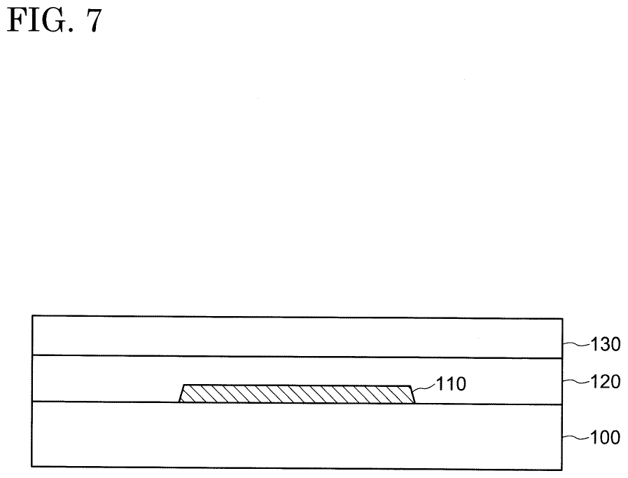

In step S1020, the nitride insulating layer 120 and the first oxide insulating layer 130 are sequentially formed on the light shielding layer 110 (see FIG. 7). The nitride insulating layer 120 and the first oxide insulating layer 130 are deposited by CVD. When silicon nitride and silicon oxide are used for the nitride insulating layer 120 and the first oxide insulating layer 130, respectively, the silicon nitride and the silicon oxide can be deposited successively by switching the gas supplied into the chamber. Although the thickness of the nitride insulating layer 120 is not limited to a certain value, the thickness is greater than or equal to 50 nm and less than or equal to 500 nm, and preferably greater than or equal to 150 nm and less than or equal to 300 nm. Although the thickness of the first oxide insulating layer 130 is also not limited to a certain value, the thickness is greater than or equal to 50 nm and less than or equal to 500 nm, and preferably greater than or equal to 150 nm and less than or equal to 300 nm.

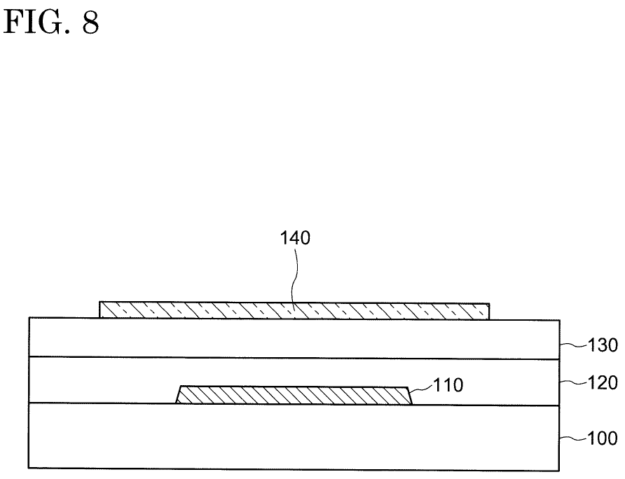

In step S1030, the oxide semiconductor layer 140 is deposited on the first oxide insulating layer 130, and then patterned using photolithography. In this way, the oxide semiconductor layer 140 having a predetermined pattern shape is formed on the first oxide insulating layer 130 (see FIG. 8). The oxide semiconductor layer 140 is deposited by sputtering. The thickness of the oxide semiconductor layer 140 is greater than or equal to 10 nm and less than or equal to 100 nm, preferably greater than or equal to 15 nm and less than or equal to 70 nm, and more preferably greater than or equal to 15 nm and less than or equal to 50 nm. The oxide semiconductor layer 140 may be patterned by dry etching or wet etching. In the case of wet etching, the oxide semiconductor layer 140 can be etched using an acidic etching solution. For example, oxalic acid, PAN, sulfuric acid, hydrogen peroxide, or hydrofluoric acid can be used as the etching solution.

The oxide semiconductor layer 140 after deposition may have an amorphous structure or a crystalline structure (for example, a structure having microcrystals).

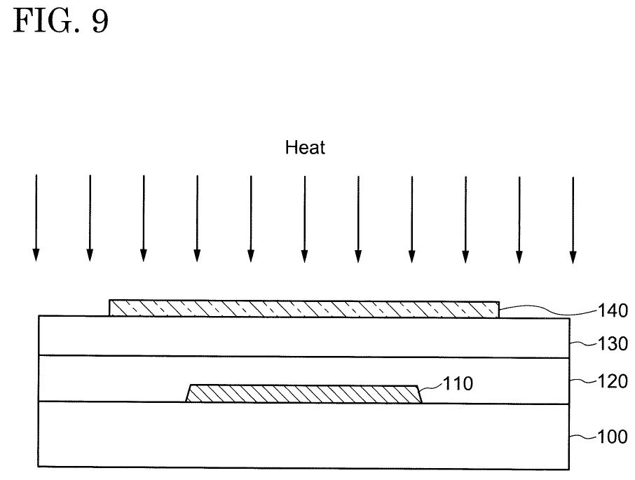

In step S1040, a heat treatment is performed on the oxide semiconductor layer 140 having a predetermined pattern (see FIG. 9). Hereinafter, for convenience of explanation, the heat treatment performed on the exposed oxide semiconductor layer 140 may be referred to as an “OS annealing process.” In the OS annealing process, since the metal elements in the oxide semiconductor layer 140 are rearranged and the bond distances are adjusted, the film quality of the oxide semiconductor layer 140 is made uniform. When the OS annealing process is performed on the oxide semiconductor layer 140 having an amorphous structure, the oxide semiconductor layer 140 may have short-range order or microcrystals. Further, when the OS annealing process is performed on the oxide semiconductor layer 140 having a crystalline structure, the grain size of the microcrystals may increase.

The reaching temperature in the OS annealing process is higher than or equal to 300° C. and lower than or equal to 500° C., and preferably higher than or equal to 350° C. and lower than or equal to 450° C. Further, the holding time at the reaching temperature in the OS annealing process is greater than or equal to 15 minutes and less than or equal to 120 minutes, and preferably greater than or equal to 30 minutes and less than or equal to 60 minutes. Furthermore, the atmosphere in the OS annealing process is air.

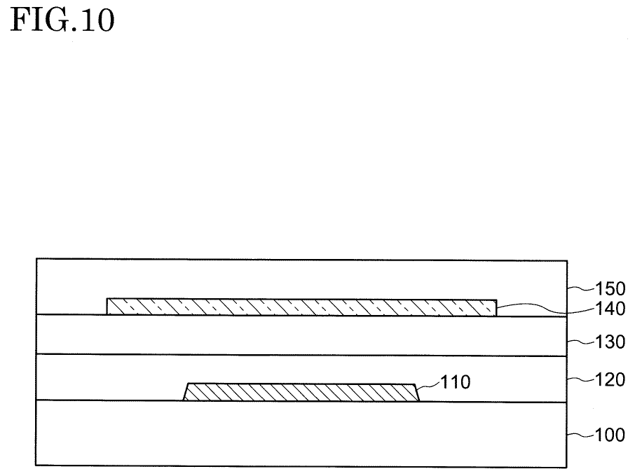

In step S1050, the second oxide insulating layer 150 is formed over the oxide semiconductor layer 140 (see FIG. 10). In this way, the oxide semiconductor layer 140 is covered with the second oxide insulating layer 150. The second oxide insulating layer 150 is deposited by CVD. The second oxide insulating layer 150 functions as a gate insulating layer. It is preferable that the second oxide insulating layer 150 has a large thickness so that the semiconductor device 10 has a high breakdown voltage. The thickness of the second oxide insulating layer 150 is greater than or equal to 200 nm, preferably greater than or equal to 250 nm, and more preferably greater than or equal to 300 nm. Although the upper limit of the thickness of the second oxide insulating layer 150 is not limited to a certain value, the thickness is less than or equal to 500 nm.

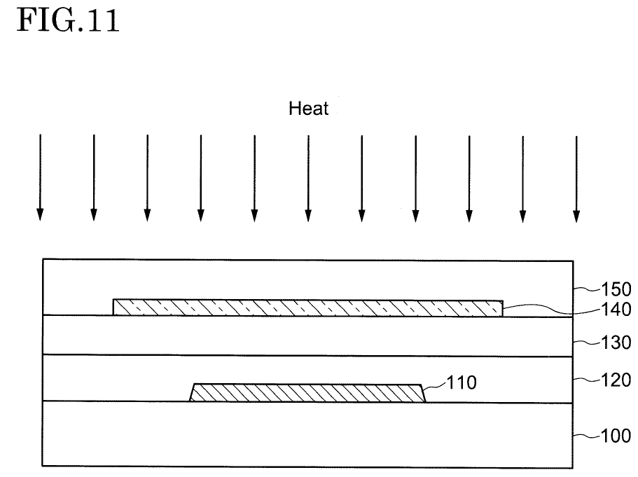

In step S1060, a heat treatment is performed on the oxide semiconductor layer 140 covered with the second oxide insulating layer 150 (see FIG. 11). Many oxygen deficiencies are generated in the oxide semiconductor layer 140 due to the formation of the second oxide insulating layer 150. Therefore, a heat treatment is performed after the formation of the second oxide insulating layer 150 to supply oxygen from the first oxide insulating layer 130 or the second oxide insulating layer 150 to the oxide semiconductor layer 140, so that the oxygen deficiencies in the oxide semiconductor layer 140 are repaired. Hereinafter, for convenience of explanation, the heat treatment for repairing the oxygen deficiencies in the oxide semiconductor layer 140 may be referred to as an “oxidation annealing process.”

The conditions for the oxidation annealing process are similar to those for the OS annealing process. In the oxidation annealing process, a heat treatment may be performed after a metal oxide film is deposited on the second oxide insulating layer 150. Since the metal oxide layer suppresses oxygen being released from the second oxide insulating layer 150 into the atmosphere, oxygen can be efficiently supplied to the oxide semiconductor layer 140 during the oxidation annealing process. An aluminum oxide film such as silicon oxide (AlOₓ) or aluminum oxynitride (AlOₓN_{y}), a transparent conductive oxide such as indium tin oxide (ITO) or indium zinc oxide (IZO), or a transparent oxide such as indium gallium tin oxide (IGZO) can be used for the metal oxide film. Here, aluminum oxynitride (AlOₓN_{y}) is an aluminum compound that contains a smaller proportion (x>y) of nitrogen (N) than oxygen (O). After the oxidation annealing process, the metal oxide film is removed.

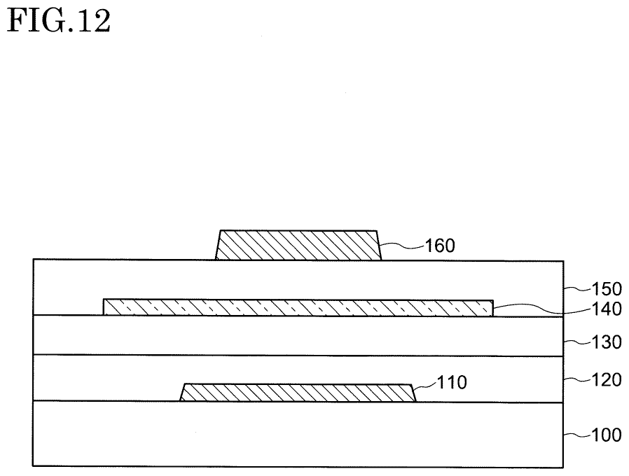

In step S1070, the gate electrode 160 is deposited on the second oxide insulating layer 150, and then patterned using photolithography. In this way, the gate electrode 160 having a predetermined pattern shape is formed on the second oxide insulating layer 150 (see FIG. 12). The gate electrode 160 is deposited by sputtering. Although the thickness of the gate electrode 160 is not limited to a certain value, the thickness is greater than or equal to 100 nm and less than or equal to 500 nm, for example.

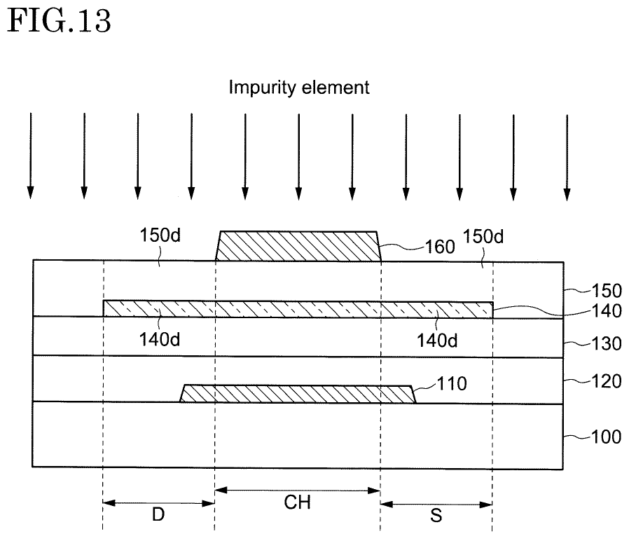

In step S1080, an impurity element is added to the oxide semiconductor layer 140. The impurity element is added to the oxide semiconductor layer 140 through the second oxide insulating layer 150 using the gate electrode 160 as a mask (see FIG. 13). In this way, the channel region CH overlapping the gate electrode 160 and not containing the impurity element, and the source region S and the drain region D (i.e., the first region 140d) not overlapping the gate electrode 160 and containing the impurity element are formed in the oxide semiconductor layer 140. Further, the second region 150d overlapping the first region 140d and containing the impurity element is formed in the second oxide insulating layer 150.

Boron, phosphorus, argon, nitrogen, or the like can be used as the impurity element. The impurity element is added to the oxide semiconductor layer 140 by ion implantation, ion doping, or the like. At this time, the addition conditions of the impurity element (for example, the dose or the acceleration voltage) are controlled so that the concentration profile of the impurity element has a peak in the second region 150d. Specifically, in the concentration profile of the impurity element, the peak is located within 50 nm from the interface between the first region 140d and the second region 150d (i.e., the interface between the oxide semiconductor layer 140 and the second oxide insulating layer 150). Further, the addition conditions of the impurity element are controlled so that the concentration of the impurity element in the surface of the first region 140d on the first oxide insulating layer 130 side is less than or equal to 5×10¹⁸ cm⁻³ and the concentration of the impurity element in the surface of the first region 140d on the second oxide insulating layer 150 side is greater than or equal to 5×10¹⁹ cm⁻³. In this way, not only are the resistances of the source region S and the drain region D reduced, but also the variations in the electrical characteristics of the semiconductor device 10 are suppressed.

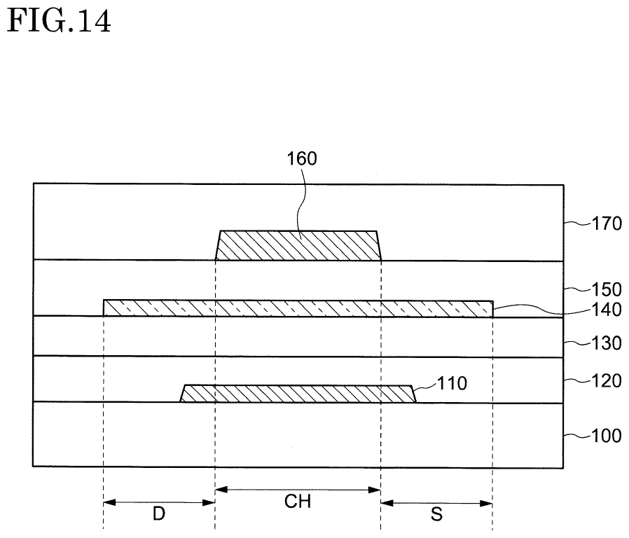

In step S1090, the third oxide insulating layer 170 is formed on the gate electrode 160 (see FIG. 14). In this way, the gate electrode 160 is covered with the third oxide insulating layer 170. The third oxide insulating layer 170 is deposited by CVD. Although the thickness of the third oxide insulating layer 170 is not limited to a certain value, the thickness is greater than or equal to 50 nm and less than or equal to 500 nm, and preferably greater than or equal to 200 nm and less than or equal to 400 nm.

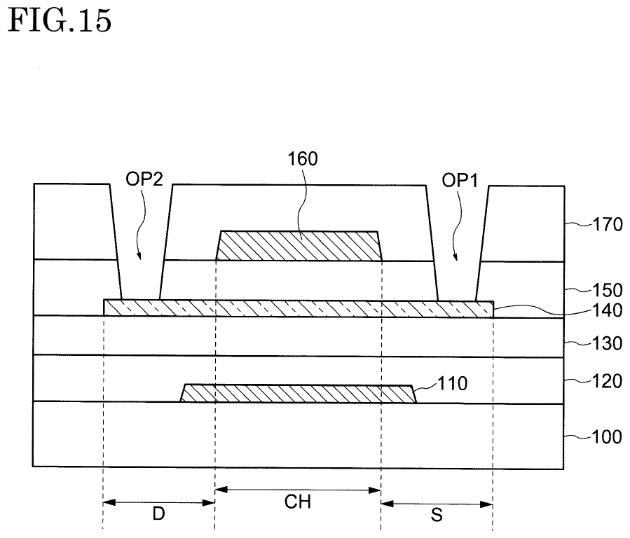

In step S1100, the opening portions OP1 and OP2 are formed in the second oxide insulating layer 150 and the third oxide insulating layer 170 (see FIG. 15). In this way, the source region S and the drain region D are exposed in the opening portions OP1 and OP2, respectively.

In step S1110, a conductive film is deposited on the third oxide insulating layer 170, and then patterned using photolithography. In this way, the source electrode 180 is electrically connected to the source region S through the opening portion OP1 and the drain electrode 190 is electrically connected to the drain region D through the opening portion OP2, thereby manufacturing the semiconductor device 10 shown in FIG. 1.

Although detailed description is omitted, the semiconductor device 10 may include a nitride insulating layer in contact with the third oxide insulating layer 170 so as to cover the source electrode 180 and the drain electrode 190. In general, a nitride insulator contains more hydrogen than an oxide insulator. Therefore, when a nitride insulator layer is formed on the third oxide insulating layer 170, hydrogen in the nitride insulating layer diffuses into the oxide semiconductor layer 140 and is trapped by oxygen deficiencies in the source region S and the drain region D. Since carriers are generated in the source region S and the drain region D that trap hydrogen, the source region S and the drain region D are conductive. That is, the electrical conductivity of the source region S and the drain region D increases. Since oxygen deficiencies are not generated in the channel region CH, the electrical conductivity of the channel region CH does not increase. Therefore, the channel region CH has semiconductor properties.

According to the present embodiment, the concentration profile of the impurity element is controlled in the semiconductor device 10 including the second oxide insulating layer 150 having a thickness four or more times that of the oxide semiconductor layer 140. Thus, the generation of more hydrogen than necessary in the second oxide insulating layer 150 is suppressed while generating oxygen deficiencies in the oxide semiconductor layer 140. Therefore, since hydrogen generated in the second oxide insulating layer 150 does not diffuse to the channel region CH in the semiconductor device 10, variations in electrical characteristics are suppressed. Further, since the second oxide insulating layer 150, which functions as a gate insulating film, has a large thickness, the semiconductor device 10 has a high breakdown voltage. For example, the semiconductor device 10 has a breakdown voltage greater than or equal to 30 V.

Each of the embodiments and modifications described above as the embodiments of the present invention can be appropriately combined and implemented as long as no contradiction is caused. Further, the addition, deletion, or design change of components, or the addition, deletion, or condition change of processes as appropriate by those skilled in the art based on each of the embodiments and modifications are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device, comprising:
an oxide insulating layer;
an oxide semiconductor layer over and in contact with the oxide insulating layer;
a gate insulating layer over and in contact with the oxide semiconductor layer; and
a gate electrode over the gate insulating layer,
wherein a thickness of the gate insulating layer is greater than or equal to 200 nm,
wherein the oxide semiconductor layer comprises a first region not overlapping the gate electrode in a thickness direction and contains an impurity element,
wherein the gate insulating layer comprises a second region overlapping the first region in the thickness direction and contains the impurity element,
wherein a concentration profile of the impurity element in the thickness direction has a peak in the second region,
wherein a concentration of the impurity element in a surface of the first region on the oxide insulating layer side is less than or equal to 5×10¹⁸ cm⁻³; and
wherein a concentration of the impurity element in a surface of the first region on the gate insulating layer side is greater than or equal to 5×10¹⁹ cm⁻³.

2. The semiconductor device according to claim 1, wherein the peak is located within 50 nm from an interface between the oxide semiconductor layer and the gate insulating layer.

3. The semiconductor device according to claim 1, wherein a thickness of the oxide semiconductor layer is greater than or equal to 10 nm and less than or equal to 50 nm.

4. The semiconductor device according to claim 3, wherein a sheet resistance of the first region is less than or equal to 1×10⁴ Ω/sq.

5. The semiconductor device according to claim 1, further comprising a source electrode and a drain electrode,
wherein when a voltage of 5 V is applied to the gate electrode of the semiconductor device having a channel length of 3 μm, a breakdown voltage between the source electrode and the drain electrode is greater than or equal to 30 V.

6. The semiconductor device according to claim 1, wherein the impurity element is one selected from the group consisting of boron, phosphorus, argon, and nitrogen.
